(19) United States
(12) Patent Application Publication
(10) Pub. No.: US 2019/0244809 A1
(43) Pub. Date: Aug. 8, 2019

(54) CHEMICAL LIQUID APPLICATION APPARATUS AND MANUFACTURING METHOD OF SEMICONDUCTOR DEVICE

(71) Applicant: Toshiba Memory Corporation, Minato-ku (JP)

(72) Inventor: Yoshiharu ONO, Yokkaichi (JP)

(73) Assignee: Toshiba Memory Corporation, Minato-ku (JP)

(21) Appl. No.: 16/104,176

(22) Filed: Aug. 17, 2018

(30) Foreign Application Priority Data
Feb. 5, 2018 (JP) 2018-018539

(51) Int. Cl. H01L 21/02; B05C 5/00; H01L 21/66

(52) U.S. Cl. CPC H01L 21/02087; H01L 22/12; H01L 21/02282; B05C 5/004

(57) ABSTRACT

A chemical liquid application apparatus of an embodiment is a chemical liquid application apparatus that applies a chemical liquid to a substrate and removes the chemical liquid on an edge of the substrate by a predetermined width in a state where the substrate is being rotated by a spinner. The chemical liquid application apparatus includes a detection unit that detects a position of a mark on the substrate, a transfer unit that transfers the substrate onto the spinner, and a control unit that calculates a center position of a shot map from the position of the mark and controls the transfer unit to cause the center position of the shot map to coincide with a rotating center of the spinner when the transfer unit transfers the substrate onto the spinner.

### CROSS-REFERENCE TO RELATED APPLICATIONS

This application is based upon and claims the benefit of priority from Japanese Patent Application No. 2018-018539, filed on Feb. 5, 2018; the entire contents of which are incorporated herein by reference.

### FIELD

Embodiments of the present invention described herein relate generally to a chemical liquid application apparatus and a manufacturing method of a semiconductor device.

### BACKGROUND

Manufacturing processes of a semiconductor device include a process to form an application film by applying chemical liquid onto a substrate. When forming the application film, the chemical liquid applied on edges of the substrate is removed.

By the way, in a conventional technique, for example, there is room for further improvement in accuracy of removing the chemical liquid applied on the edges of the substrate.

### BRIEF DESCRIPTION OF THE DRAWINGS

FIG. 1 is a diagram illustrating an entire configuration of a chemical liquid application apparatus according to a first embodiment;

FIG. 2 is a diagram illustrating a configuration example of a detection unit of the chemical liquid application apparatus according to the first embodiment;

FIG. 3 is a schematic diagram illustrating a situation where the detection unit according to the first embodiment detects a mark on a wafer;

FIG. 4 is a schematic diagram illustrating a relationship between a center position of the wafer and a center position of a shot map;

FIG. 5 is a schematic diagram illustrating a configuration example of an application unit of the chemical liquid application apparatus according to the first embodiment;

FIG. 6 is a flowchart illustrating an example of a procedure of chemical liquid application processing of the chemical liquid application apparatus according to the first embodiment;

FIG. 7 is a schematic diagram when an SOC film is formed by the chemical liquid application apparatus according to the first embodiment and an SOC film is formed by a chemical liquid application apparatus according to a comparative example;

FIG. 8 is a diagram illustrating an entire configuration of a chemical liquid application apparatus according to a second embodiment;

FIG. 9 is a diagram illustrating a configuration example of a cooling unit of the chemical liquid application apparatus according to the second embodiment; and

FIG. 10 is a flowchart illustrating an example of a procedure of chemical liquid application processing of the chemical liquid application apparatus according to the second embodiment.

### DETAILED DESCRIPTION

A chemical liquid application apparatus of an embodiment is a chemical liquid application apparatus that applies a chemical liquid to a substrate and removes the chemical liquid on an edge of the substrate by a predetermined width in a state where the substrate is being rotated by a spinner. The chemical liquid application apparatus includes a detection unit that detects a position of a mark on the substrate, a transfer unit that transfers the substrate onto the spinner, and a control unit that calculates a center position of a shot map from the position of the mark and controls the transfer unit to cause the center position of the shot map to coincide with a rotating center of the spinner when the transfer unit transfers the substrate onto the spinner.

Hereinafter, the present invention will be described in detail with reference to the drawings. The present invention is not limited by embodiments described below. Components described below include components easily conceivable by those skilled in the art and components substantially identical thereto.

### First Embodiment

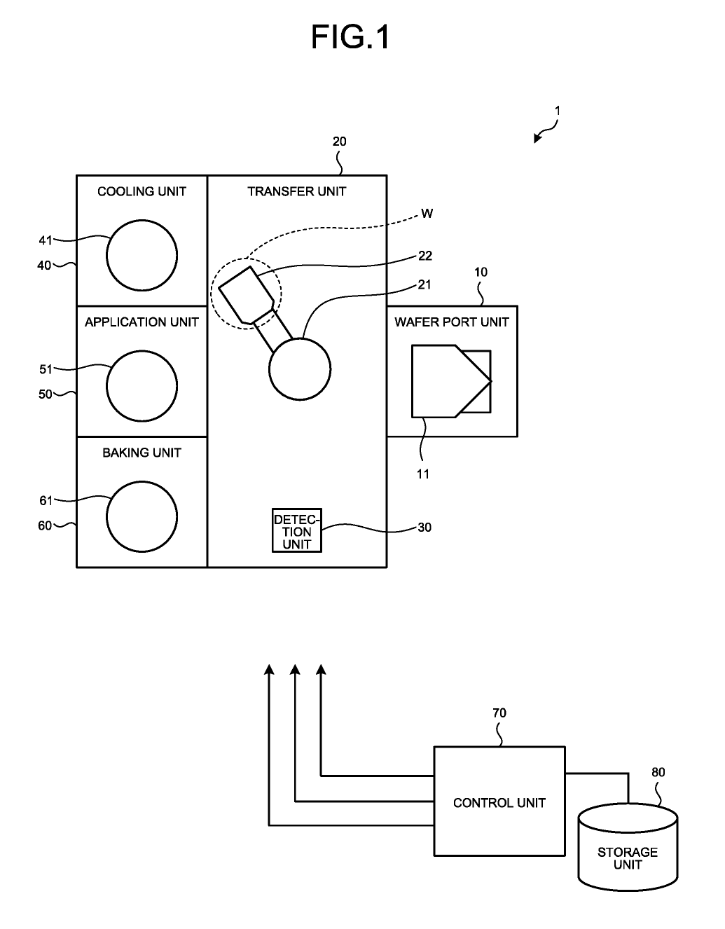

A first embodiment and a modified example will be described with reference to FIGS. 1 to 7.

(Configuration Example of Chemical Liquid Application Apparatus)

FIG. 1 is a diagram illustrating an entire configuration of a chemical liquid application apparatus 1 according to a first embodiment. The chemical liquid application apparatus 1 applies chemical liquid onto a wafer W uses as a substrate and forms an application film. The application film is, for example, an SOC (Spin On Carbon) film with a thickness of about 100 nm.

As illustrated in FIG. 1, the chemical liquid application apparatus 1 includes a wafer port unit 10, a transfer unit 20, a detection unit 30, a cooling unit 40, an application unit 50, a baking unit 60, and a control unit 70.

The wafer port unit 10 carries the wafer W into or out of the chemical liquid application apparatus 1. Specifically, the wafer port unit 10 is mounted with a wafer storage container 11 such as a wafer cassette or a wafer pod. The wafer W is carried into the chemical liquid application apparatus 1 from the wafer storage container 11 and the wafer W is carried from inside the chemical liquid application apparatus 1 to the wafer storage container 11.

The transfer unit 20 is provided adjacent to the wafer port unit 10. The transfer unit 20 is provided with a transfer robot 21. The transfer robot 21 includes a transfer arm 22, and transfers the wafer W between the transfer unit 20 and the wafer port unit 10, the cooling unit 40, the application unit 50, and the baking unit 60.

The transfer unit 20 is also provided with the detection unit 30. The detection unit 30 detects a mark (not illustrated in the drawings) of the wafer W supported by the transfer arm 22. Details of the detection unit 30 will be described later.

The cooling unit 40, the application unit 50, and the baking unit 60 are provided in this order along and adjacent to the transfer unit 20 on the side of the transfer unit 20 opposite to the side facing the wafer port unit 10.

The cooling unit 40 includes a cooling plate 41 and stabilizes the temperature of the wafer W. The temperature of the wafer W carried in from the outside of the chemical liquid application apparatus 1 varies according to the previous process and the like. The cooling unit 40 holds the wafer W on the cooling plate 41 until the temperature of the wafer W is stabilized to a predetermined temperature.

The application unit 50 includes a spinner 51. The spinner 51 holds the wafer W and rotates the wafer W in a horizontal plane. The application unit 50 applies chemical liquid onto the wafer W while the wafer W is being rotated. The chemical liquid contains, for example, a component of an SOC film and a solvent in which the component is dissolved. Further, the application unit 50 removes the chemical liquid applied to the edges of the wafer W by using a dissolving liquid such as thinner.

The baking unit 60 includes a hot plate 61 and heats the wafer W. The baking unit 60 holds the wafer W on the hot plate 61 until the solvent in the chemical liquid on the wafer W is evaporated and components in the chemical liquid are solidified. Thereby, an SOC film is formed on the wafer W.

The control unit 70 is configured as a computer including, for example, a hardware processor such as a CPU (Central Processing Unit), a memory, and an HDD (Hard Disk Drive). The control unit 70 controls the wafer port unit 10, the transfer unit 20, the detection unit 30, the cooling unit 40, the application unit 50, and the baking unit 60.

A storage unit 80 is connected to the control unit 70. The storage unit 80 stores position information of the mark of the wafer W detected by the detection unit 30 and an offset value of a shot map described later.

After the processing in the chemical liquid application apparatus 1, for example, the wafer W is applied with resist and patterned by an imprint apparatus. The imprint apparatus is an apparatus that transfers a template pattern to the resist on the wafer W. The SOC film formed on the wafer W is thereafter used as a mask along with the patterned resist.

(Configuration Example of Detection Unit)

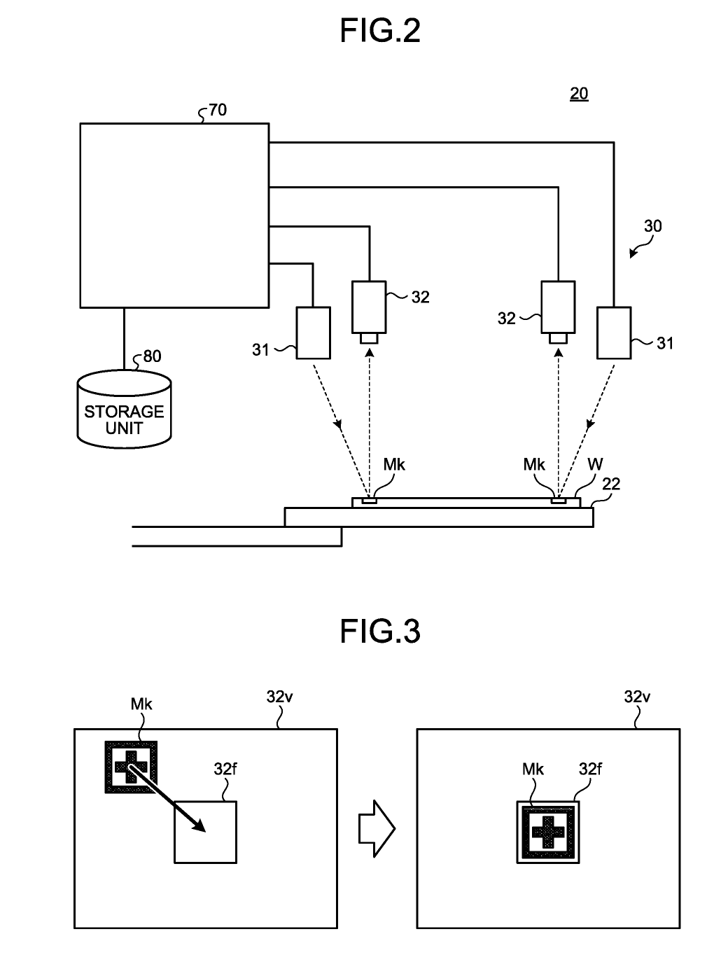

Next, a configuration of the detection unit 30 will be described with reference to FIGS. 2 to 4. FIG. 2 is a diagram illustrating a configuration example of the detection unit 30 of the chemical liquid application apparatus 1 according to the first embodiment.

As illustrated in FIG. 2, the detection unit 30 includes a plurality of light sources 31 and a plurality of imaging elements 32. For example, the light sources 31 and the imaging elements 32 are provided on a top plate (not illustrated in the drawings) of the transfer unit 20 and arranged above the wafer W held on the transfer arm 22.

The plurality of light sources 31 emits light to the wafer W. At this time, a plurality of marks Mk formed on the wafer W is also irradiated with the light. As described later, a plurality of shots is formed on the wafer W according to a shot map. The center position of the shot map is indicated by the plurality of marks Mk.

The plurality of imaging elements 32 is CCDs or CMOS sensors and is respectively provided corresponding to the light sources 31. The imaging elements 32 respectively detect the marks Mk of the wafer W irradiated with the light from the light sources 31. The detection of the marks Mk is performed by using, for example, a general image recognition technique. Image information obtained by the imaging elements 32 is appropriately transmitted to the control unit 70.

FIG. 3 is a schematic diagram illustrating a situation where the detection unit 30 according to the first embodiment detects the mark Mk on the wafer W.

As illustrated in FIG. 3, in a visual field 32v of the imaging element 32, for example, a cross-shaped mark Mk surrounded by a square frame is visible. The control unit 70 controls the transfer robot 21 to move the transfer arm 22 so that the mark Mk is located within a frame 32f in the center of the visual field 32v of the imaging element 32. The control unit 70 obtains the position information of the mark Mk of the wafer W from the position of the transfer arm 22 at this time. The obtained position information of the mark Mk is stored in the storage unit 80.

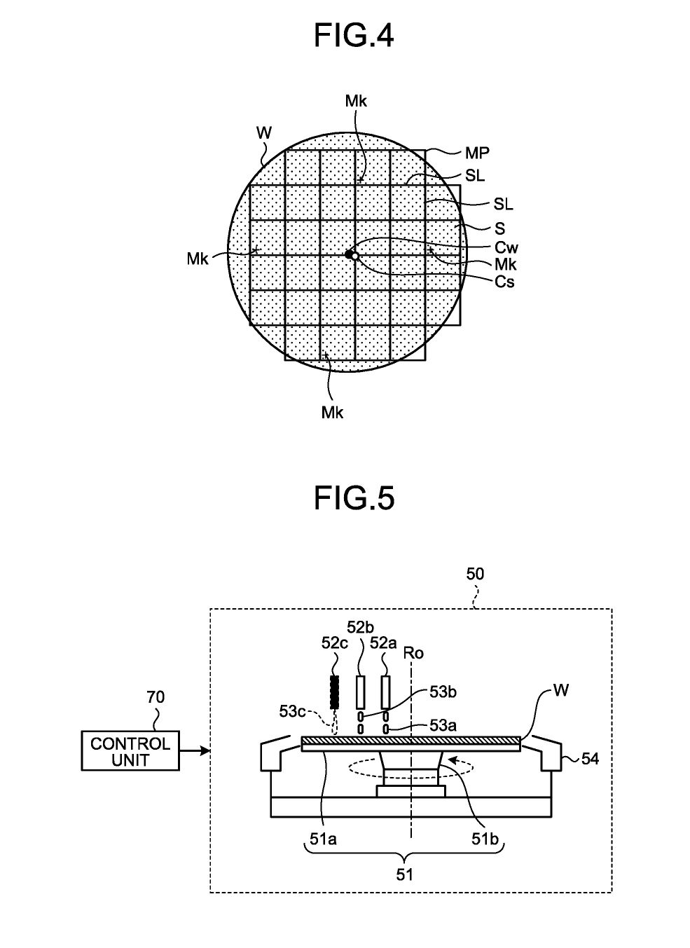

FIG. 4 is a schematic diagram illustrating a relationship between a center position Cw of the wafer W and a center position Cs of a shot map MP.

As illustrated in FIG. 4, a plurality of shots S is formed in the wafer W according to the shot map MP. Among the shots S, scribe lines SL which are used as dicing lines when the semiconductor device is cut out into chips are arranged in a lattice shape. The center position Cs of the shot map MP may be shifted from the physical center position Cw of the wafer W by about several tens of μm. This is because there is no reference for positioning on the wafer W when performing patterning on a first layer of the wafer W, so that accuracy of positioning by an exposure apparatus is low. Further, there is a case where an offset for intentionally shifting the center position Cs of the shot map MP is added in order to set more shots S on one wafer W and obtain more semiconductor devices from the one wafer W. The offset value is, for example, stored in the storage unit 80.

The mark Mk is, for example, arranged at a predetermined position in the shot S for all the shots S. In FIG. 4, the marks Mk are illustrated in only predetermined shots S on the outermost circumference. The center position Cs of the shot map MP can be calculated from coordinates in the shot map MP of the mark Mk provided in each shot S and a size of each shot S. In other words, the control unit 70 calculates the center position Cs of the shot map MP in the wafer W from the position information of the mark Mk detected by the detection unit 30. The control unit 70 refers to the storage unit 80, and when the offset value is set in the shot map MP, the control unit 70 calculates the center position Cs of the shot map MP by considering the offset value. When the wafer W is transferred to the application unit 50, the control unit 70 controls the transfer robot 21 and causes a rotating center of the spinner 51 and the center position Cs of the shot map MP in the wafer W to coincide with each other.

(Configuration Example of Application Unit)

Next, a configuration of the application unit 50 will be described with reference to FIG. 5. FIG. 5 is a schematic diagram illustrating a configuration example of the application unit 50 of the chemical liquid application apparatus 1 according to the first embodiment. The application unit 50 forms, for example, an SOC film on the wafer W by a spin coating method.

As illustrated in FIG. 5, the application unit 50 includes the spinner 51, a plurality of nozzles 52a, 52b, and 52c, and a cup 54.

The spinner 51 includes a support table 51a and a spin motor 51b. The support table 51a has an approximately disc-shaped upper surface. The wafer W is mounted on the upper surface of the support table 51a. The support table 51a has a spin chuck not illustrated in the drawings. The spin chuck fixes and holds the wafer W by vacuum contact.

The spin motor 51b is provided below the support table 51a. The spin motor 51b rotates the wafer W supported by the support table 51a by rotating the support table 51a around a rotation axis Ro at a predetermined rotation rate. The spin motor 51b rotates the wafer W so as to spread the chemical liquid dropped on the wafer W in the radial direction of the wafer W (toward an edge) by centrifugal force. The spin motor 51b throws off the chemical liquid remained on the wafer W by centrifugal force by rotating the wafer W at a predetermined speed.

The cup 54 is arranged on the edge side of the support table 51a. The cup 54 has an annular ring shape so as to be able to receive the chemical liquid thrown out from the wafer W. The cup 54 collects the chemical liquid thrown out from the wafer W.

Each of the plurality of nozzles 52a, 52b, and 52c is configured to send a predetermined chemical liquid or the like onto the wafer W. Each of the nozzles 52a, 52b, and 52c is installed at a tip portion of a scan arm not illustrated in the drawings and is moved by the scan arm. These scan arms are installed so as to be able to move between the center position and an edge position of the wafer W. Further, each of the nozzles 52a, 52b, and 52c is connected to a supply pipe not illustrated in the drawings, and a tank not illustrated in the drawings is connected to each supply pipe. Thereby, each of the nozzles 52a, 52b, and 52c can supply a predetermined chemical liquid or the like while moving along a radial direction of the wafer W.

For example, when forming an SOC film on the wafer W, the nozzle 52a drops droplets of an SOC liquid 53a, where components of the SOC film are dissolved in a solvent, to a central portion of the rotating wafer W. The dropped SOC liquid 53a wet-spreads toward the edge side of the wafer W by centrifugal force applied to the wafer W. The SOC liquid 53a that reaches the edge of the wafer W is thrown out from the wafer W and collected by the cup 54.

The nozzle 52b drops droplets of thinner 53b onto the wafer W while moving over the wafer W from the edge to the center position. The thinner 53b is a liquid whose surface tension is higher than the surface tension of the SOC liquid 53a. Therefore, the thinner 53b is prevented from wet-spreading toward the center position of the wafer W beyond the moving position of the nozzle 52b. On the other hand, excessive thinner 53b on the edge side of the wafer W is thrown out from the wafer W and collected by the cup 54. Thereby, a predetermined width of the SOC liquid 53a from the edge of the wafer W is removed. This processing is called an edge removal or an edge cut.

The nozzle 52c blows N₂ gas 53c onto the wafer W while moving over the wafer W from the edge to the center position. The nozzle 52c moves in accordance with the nozzle 52b that moves while dropping droplets of the thinner 53b. Thereby, the thinner 53b dropped on the wafer W is promptly dried and the thinner 53b is further prevented from wet-spreading.

The control unit 70 controls the amount of the SOC liquid 53a sent from the nozzle 52a, the amount of the thinner 53b sent from the nozzle 52b, the amount of the N₂ gas 53c sent from the nozzle 52c.

The control unit 70 also controls a position and a moving speed of the nozzle 52a over the wafer W. The control unit 70 also controls a moving speed of the nozzle 52b for each position (droplet dropping position) on the wafer W. The control unit 70 also controls movement of the nozzle 52c so that a moving speed of the nozzle 52c is the same as the moving speed of the nozzle 52b.

By the way, in the chemical liquid application apparatus 1 of the first embodiment, the wafer W is mounted on the support table 51a so that the center position Cs of the shot map MP in the wafer W is coincident with the rotating center of the spinner 51 (a point on the rotation axis Ro).

Therefore, when the SOC liquid 53a on the wafer W is removed, the SOC liquid 53a from a position the same distance away from the center position Cs of the shot map MP in the wafer W instead of a position the same distance away from the center position Cw of the wafer W to the end portion of the wafer W is removed. In other words, the SOC liquid 53a is not removed in a uniform width from the end portion of the wafer W, but a removal width of the SOC liquid 53a varies according to an edge position.

(Example of Chemical Liquid Application Processing)

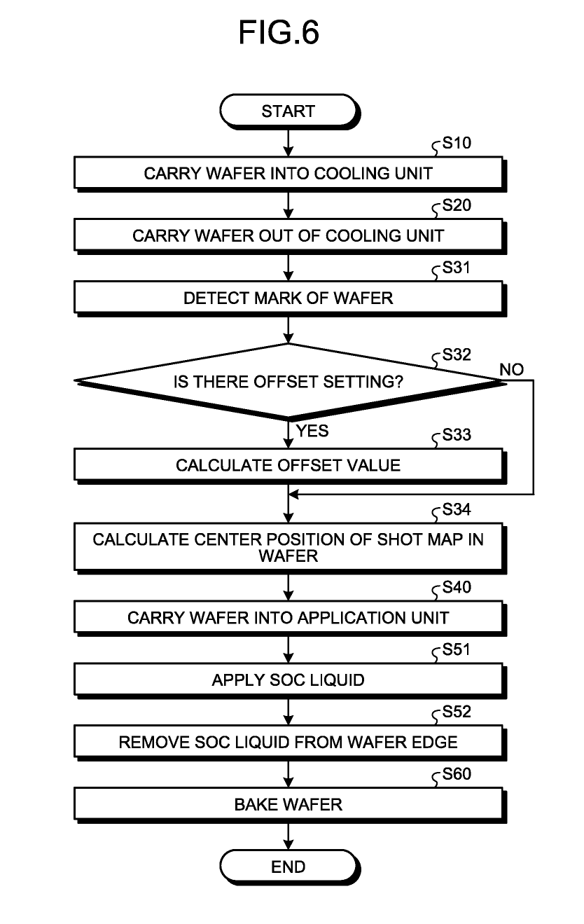

Next, an example of chemical liquid application processing will be described as a process of manufacturing processing of a semiconductor device in the chemical liquid application apparatus 1 with reference to FIG. 6. FIG. 6 is a flowchart illustrating an example of a procedure of the chemical liquid application processing of the chemical liquid application apparatus 1 according to the first embodiment.

As illustrated in FIG. 6, in Step S10, the control unit 70 controls the transfer robot 21 of the transfer unit 20 and carries the wafer W into the cooling unit 40. In Step S20, the control unit 70 controls the transfer robot 21 and carries the wafer W out of the cooling unit 40 to the transfer unit 20.

In Step S31, the control unit 70 controls the transfer robot 21 and arranges the wafer W held by the transfer arm 22 below the detection unit 30. Then, the control unit 70 causes the detection unit 30 to detect the mark Mk of the wafer W.

In Step S32, the control unit 70 refers to the storage unit 80 and determines whether or not there is an offset setting in the shot map MP. When there is an offset setting (Yes), the control unit 70 calculates an offset value in Step S33 and calculates the center position Cs of the shot map MP in Step S34. When there is no offset setting (No), the control unit 70 calculates the center position Cs of the shot map MP in Step S34 without calculating the offset value.

In Step S40, the control unit 70 controls the transfer robot 21 and carries the wafer W into the application unit 50. At this time, the control unit 70 carries the wafer W into the application unit 50 so that the center position Cs of the shot map MP in the wafer W is coincident with the rotating center of the spinner 51. In Step S51, the control unit 70 controls each component of the application unit 50 and applies the SOC liquid 53a onto the wafer W. In Step S52, the control unit 70 controls each component of the application unit 50 and removes the SOC liquid 53a from the edge of the wafer W. At this time, the SOC liquid 53a is removed with reference to the center position Cs of the shot map MP in the wafer W, so that the removal width of the SOC liquid 53a varies according to an edge position. When the processing of the application unit 50 is completed, the wafer W is carried out of the application unit 50.

In Step S60, the control unit 70 controls the transfer robot 21, carries the wafer W into the baking unit 60, and bakes the wafer W by controlling each component of the baking unit 60. When the processing of the baking unit 60 is completed, the wafer W is carried out of the baking unit 60 and the chemical liquid application apparatus 1.

In this way, the chemical liquid application processing in the chemical liquid application apparatus 1 is completed. The wafer W on which the SOC film is formed is carried into the imprint apparatus, for example. In the imprint apparatus, a resist is applied onto the SOC film of the wafer W. Then, a template where a fine pattern is formed is pressed against the resist and the resist is filled into recessed portions of the template. Thereafter, an ultraviolet ray is emitted and the resist is hardened. The resist from which the template is released and the SOC film under the resist become a mask when the wafer W is processed.

In the flowchart of FIG. 6, detection of the mark Mk is performed on the wafer W before being carried into the application unit 50. However, the timing of detection of the mark Mk is not limited to that illustrated in FIG. 6. For example, the detection of the mark Mk may be performed on the wafer W before being carried into the cooling unit 40.

In the present embodiment, the SOC film is formed on the wafer W. However, an application film other than the SOC film may be formed. As the other application films, for example, there are an SOG (Spin On Glass) film, an adhesive film, and the like. For example, the SOG film is formed into a film having a thickness of about 100 nm and is used as a mask along with the patterned resist. The adhesive film is, for example, an organic film formed into a film having a thickness of about several nm. The adhesive film improves adhesiveness between the resist and the wafer W. A plurality of application films selected from the SOC film, the SOG film, and the adhesive film may be stacked.

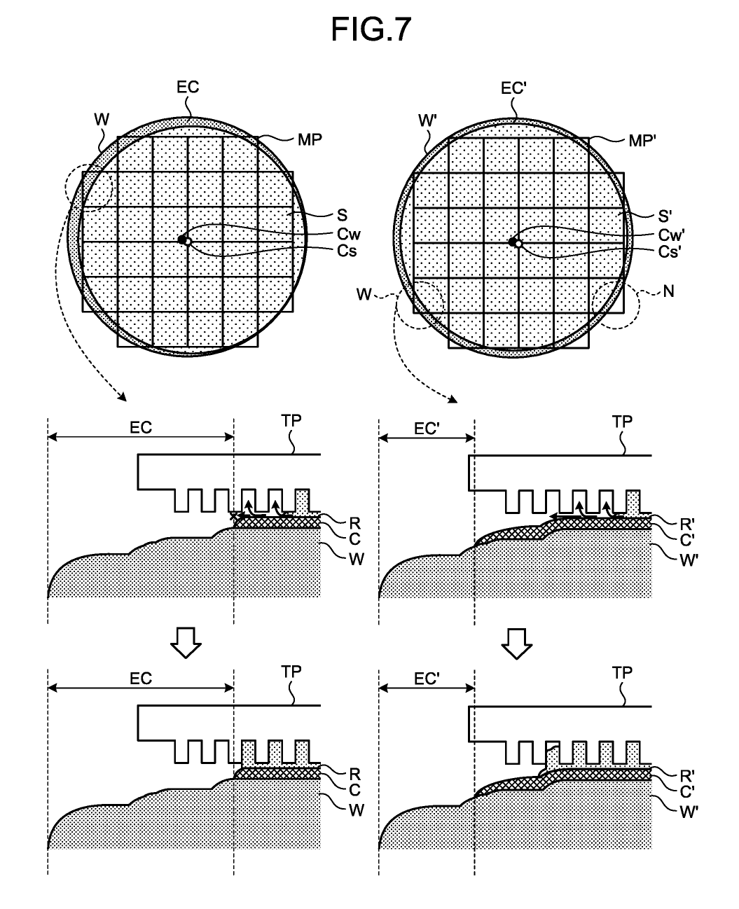

Here, the chemical liquid application apparatus 1 of the first embodiment is compared with a chemical liquid application apparatus of a comparative example with reference to FIG. 7 in order to describe an effect of the chemical liquid application apparatus 1 of the first embodiment. FIG. 7 is a schematic diagram when an SOC film is formed by the chemical liquid application apparatus 1 according to the first embodiment and an SOC film is formed by the chemical liquid application apparatus according to the comparative example. A left side of FIG. 7 is an example of the chemical liquid application apparatus 1 of the first embodiment, and a right side of FIG. 7 is an example of the chemical liquid application apparatus of the comparative example.

As illustrated in the right side of FIG. 7, in the chemical liquid application apparatus of the comparative example, a center position Cs′ of a shot map MP′ in a wafer W′ is not considered. In other words, the wafer W′ is mounted on a spinner so that a center position Cw′ of the wafer W′ is coincident with a rotating center of the spinner, and an edge cut of the wafer W′ is performed. Thereby, an edge cut portion EC′ that does not have an SOC film C′ has a uniformly equal width (about several mm) from an end portion of the wafer W′. As a result, when the center position Cs′ of the shot map MP′ is shifted from the center position Cw′ of the wafer W′, in a portion where a shot S′ is incomplete in the edge of the wafer W′, a position of the shot S′ and an edge position of the edge cut portion EC′ are relatively shifted from each other.

In the imprint apparatus, when patterning the incomplete shot S′, a resist R′ is applied to a region about 300 μm inside the edge cut portion EC′. At this time, the resist R′ is positioned by a mark formed on the wafer W′ and is dropped by an ink jet system. On the other hand, the edge position of the edge cut portion EC′ is formed with reference to the center position Cw′ of the wafer W′. Therefore, when the center position Cs′ of the shot map MP′ is shifted from the center position Cw′ of the wafer W′, a dropped position of the resist R′ and the edge position of the edge cut portion EC′ are relatively shifted from each other. When a distance between the edge cut portion EC′ and a region where the resist R′ is applied becomes small (a region N in FIG. 7) by the above shift, the resist R′ pressed by a template TP becomes excessive and easily leaks to the outside of the edge cut position. As a result, a patterning failure occurs.

When the distance between the edge cut portion EC′ and the region where the resist R′ is applied becomes large (a region W in FIG. 7), if the template TP is pressed against the edge of the wafer W′ where a shot S′ is incomplete, the resist R′ is sequentially stored into recessed portions of the template TP located on an outer side of the wafer W′ by a capillary phenomenon (in directions indicated by arrows in FIG. 7). An end portion of the wafer W′ is inclined, and the inclination has steps due to various processes that have been applied. The steps are leveled by the SOC film C′ formed there. Therefore, the resist R′ spreads outside more than anticipated due to a capillary phenomenon. As a result, a portion where a resist thickness is small is locally generated. In the imprint apparatus, the template TP is horizontally moved while the template TP is pressed against the resist R′, and positioning between a template pattern and the wafer W′ is performed. When a portion where the resist thickness is small is generated, a shear force applied to the template TP and the wafer W′ increases, so that the horizontal movement of the template TP is not performed smoothly and the positioning accuracy is degraded.

On the other hand, as illustrated on the left side of FIG. 7, in the chemical liquid application apparatus 1 of the first embodiment, the edge cut of the wafer W is performed by considering the center position Cs of the shot map MP in the wafer W. Thereby, a margin between the edge cut portion EC and a region where the resist R is applied is almost uniformly maintained over the entire circumference of the wafer W. Therefore, even in an edge portion where a shot S is incomplete, the resist R hardly leaks to the outside of the incomplete shot S, so that patterning failure is suppressed.

Further, in the chemical liquid application apparatus 1 of the first embodiment, even in an edge portion of the wafer W where a shot S is incomplete, the SOC film C is not formed on the outside of the incomplete shot S. Therefore, the SOC film C does not reach the steps of an end portion of the wafer W, and the steps are steeper than that of an end portion of the wafer W′ of the comparative example. Therefore, a force by which the resist R is moved toward the recessed portion of the template TP on the outer side of the wafer W due to a capillary phenomenon is interrupted (an arrow indicated by a mark x in FIG. 7). Thereby, it is possible to prevent the resist R from leaking to the steps on the outside of the incomplete shot S. Therefore, the patterning failure is suppressed.

### MODIFIED EXAMPLE

Next, a chemical liquid application apparatus of a modified example of the first embodiment will be described. The chemical liquid application apparatus of the modified example is different from the chemical liquid application apparatus 1 of the first embodiment in that the mark of the wafer W is a scribe line SL.

The scribe line SL of the wafer W can be detected by an image recognition function of the detection unit 30. As described above, the scribe lines SL are formed between the shots S in a lattice shape. The control unit 70 can calculate the center position Cs of the shot map MP in the wafer W by detecting the scribe lines SL.

As another detection method of the scribe lines SL of the wafer W, a method that determines areas where the shots S are formed and the scribe lines SL is known. Various patterns are formed in the shot S, so that when the detection unit 30 emits light to the shot S, scattering light is mainly obtained as reflected light from the shot S. On the other hand, scattering of reflected light hardly occurs from the scribe line SL. The detection unit 30 can determine the shots S and the scribe lines SL by determining the strength of the scattering light.

According to the chemical liquid application apparatus of the modified example, it is possible to easily detect the center position Cs of the shot map MP in the wafer W even when the mark Mk (see FIG. 3) dedicated for position detection is not provided on the wafer W.

### Second Embodiment

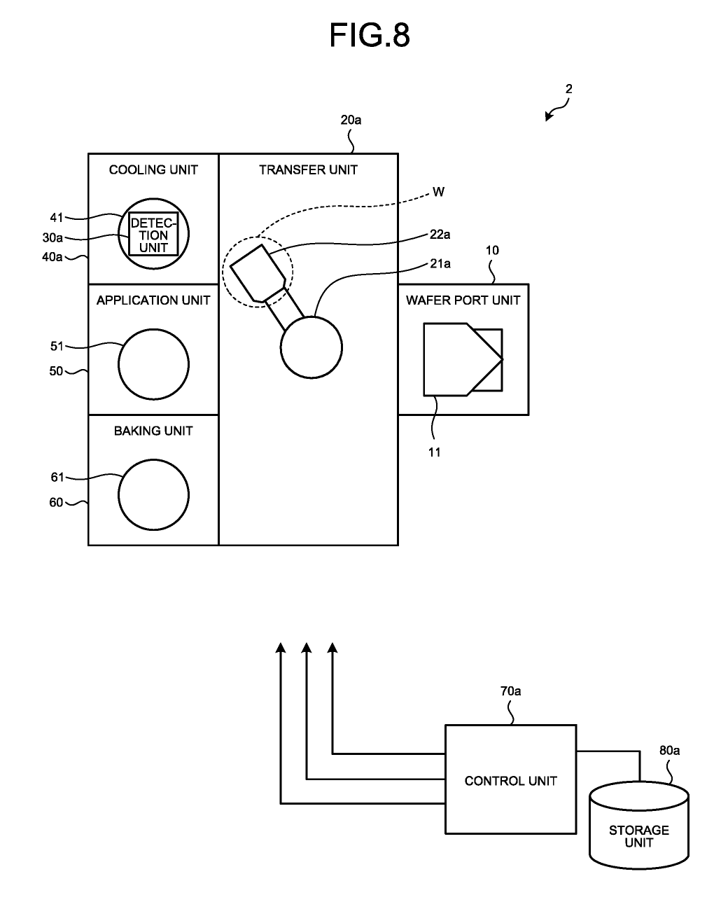

A second embodiment will be described with reference to FIGS. 8 to 10.

An entire configuration of a chemical liquid application apparatus 2 of the second embodiment will be described with reference to FIG. 8. FIG. 8 is a diagram illustrating the entire configuration of the chemical liquid application apparatus 2 according to the second embodiment. The chemical liquid application apparatus 2 of the second embodiment is different from the chemical liquid application apparatus 1 of the first embodiment in that a detection unit 30a is provided in a cooling unit 40a. The components other than the above are denoted by the same reference symbols as those of the chemical liquid application apparatus 1 of the first embodiment and the description thereof will be omitted.

As illustrated in FIG. 8, the chemical liquid application apparatus 2 includes a wafer port unit 10, a transfer unit 20a, a detection unit 30a, a cooling unit 40a as a temperature adjusting unit, an application unit 50, a baking unit 60, and a control unit 70a.

The transfer unit 20a is provided with a transfer robot 21a. The transfer robot 21a includes a transfer arm 22a, and transfers the wafer W between the transfer unit 20a and the wafer port unit 10, the cooling unit 40a, the application unit 50, and the baking unit 60.

The cooling unit 40a is installed with the detection unit 30a. The detection unit 30a detects a mark (not illustrated in the drawings) of the wafer W held by a cooling plate 41. The mark may be the mark Mk (see FIG. 3) dedicated for position detection described above or may be the scribe line SL (see FIG. 4).

The control unit 70a is configured as a computer including, for example, a hardware processor such as a CPU (Central Processing Unit), a memory, and an HDD (Hard Disk Drive). The control unit 70a controls the wafer port unit 10, the transfer unit 20a, the detection unit 30a, the cooling unit 40a, the application unit 50, and the baking unit 60.

A storage unit 80a is connected to the control unit 70a. The storage unit 80a stores position information of the mark of the wafer W detected by the detection unit 30a and an offset value of the shot map MP.

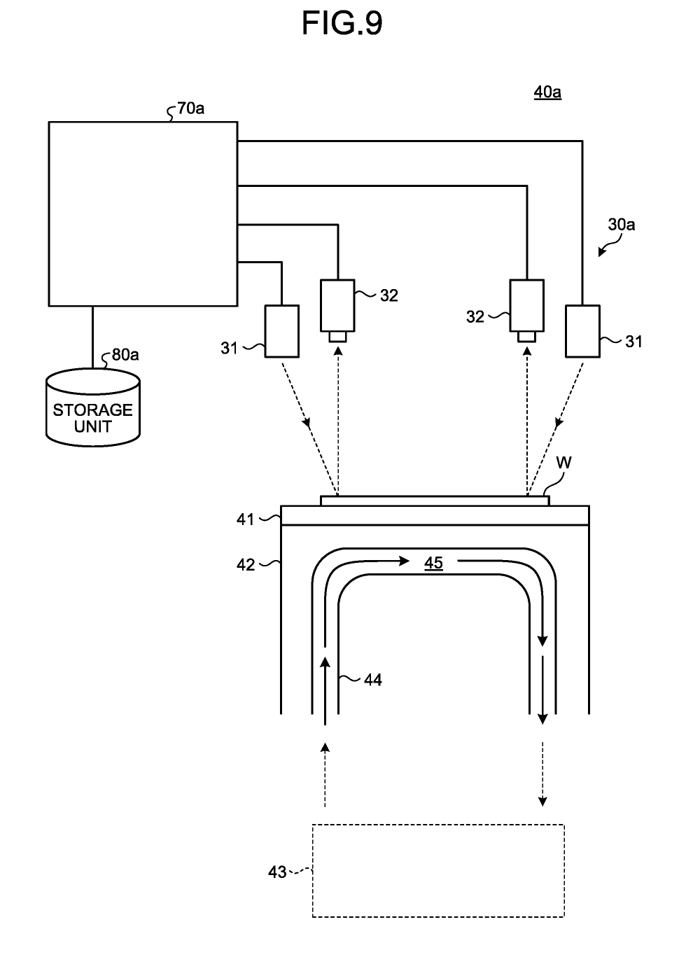

Next, a configuration of the cooling unit 40a provided with the detection unit 30a will be described with reference to FIG. 9. FIG. 9 is a diagram illustrating a configuration example of the cooling unit 40a of the chemical liquid application apparatus 2 according to the second embodiment.

As illustrated in FIG. 9, the cooling unit 40a includes the cooling plate 41. The cooling plate 41 is configured to be able to horizontally hold the wafer W. A cooling plate table 42 is provided under the cooling plate 41. The cooling plate table 42 supports the cooling plate 41. A pipe 44 connected to a chiller 43 is provided inside the cooling plate table 42. The temperature of the wafer W mounted on the cooling plate 41 is stabilized to a predetermined temperature by circulating a coolant 45 inside the pipe 44 by the chiller 43.

The detection unit 30a is provided above the cooling plate 41. The detection unit 30a is provided on a top plate (not illustrated in the drawings) of the cooling unit 40a and arranged above the wafer W held on the cooling plate 41. The other components of the detection unit 30a are denoted by the same reference symbols as those of the detection unit 30 of the first embodiment and the description thereof will be omitted.

The position information of the mark of the wafer W detected by the detection unit 30a is stored in, for example, the storage unit 80a. The control unit 70a refers to the position information and the offset value in the storage unit 80a and carries the wafer W into the application unit 50.

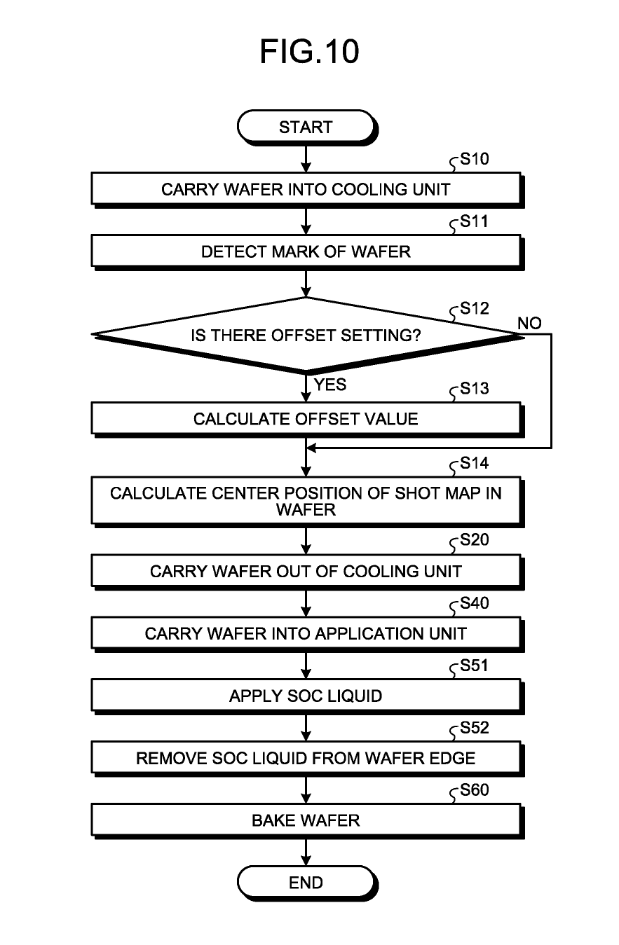

Next, an example of chemical liquid application processing will be described as a process of manufacturing processing of a semiconductor device in the chemical liquid application apparatus 2 with reference to FIG. 10. FIG. 10 is a flowchart illustrating an example of a procedure of the chemical liquid application processing of the chemical liquid application apparatus 2 according to the second embodiment.

As illustrated in FIG. 10, in Step S10, the control unit 70a controls the transfer robot 21a of the transfer unit 20a and carries the wafer W into the cooling unit 40a. Thereby, the wafer W is mounted on the cooling plate 41 and arranged below the detection unit 30a.

In Step S11, the control unit 70a causes the detection unit 30a to detect the mark of the wafer W.

In Step S12, the control unit 70a refers to the storage unit 80a and determines whether or not there is an offset setting in the shot map MP. When there is an offset setting (Yes), the control unit 70a calculates an offset value in Step S13 and calculates the center position Cs of the shot map MP in Step S14. When there is no offset setting (No), the control unit 70a calculates the center position Cs of the shot map MP in Step S14 without calculating the offset value.

In Step S20, the control unit 70a controls the transfer robot 21a and carries the wafer W out of the cooling unit 40a to the transfer unit 20a.

The steps thereafter are performed by a procedure similar to Steps S40 to S60 according to the first embodiment except that the steps are mainly performed by the control unit 70a.

In this way, the chemical liquid application processing in the chemical liquid application apparatus 2 is completed.

Also in the chemical liquid application apparatus 2 of the second embodiment, the edge cut position with respect to the shot map MP is controlled. Thereby, for example, a patterning failure of the resist in the imprint processing is suppressed.

Further, in the chemical liquid application apparatus 2 of the second embodiment, the mark of the wafer W is detected while the temperature of the wafer W is stabilized by the cooling unit 40a. Thereby, for example, different from a case where the mark is detected while the wafer W is transfered, it is possible to avoid a transfer delay. Therefore, it is possible to suppress degradation of throughput of the chemical liquid application apparatus 2

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A chemical liquid application apparatus that applies a chemical liquid to a substrate and removes the chemical liquid on an edge of the substrate by a predetermined width in a state where the substrate is being rotated by a spinner, the chemical liquid application apparatus comprising:
a detection unit that detects a position of a mark on the substrate;
a transfer unit that transfers the substrate onto the spinner; and
a control unit that calculates a center position of a shot map from the position of the mark and controls the transfer unit to cause the center position of the shot map to coincide with a rotating center of the spinner when the transfer unit transfers the substrate onto the spinner.

2. The chemical liquid application apparatus according to claim 1, wherein
the detection unit is provided in the transfer unit.

3. The chemical liquid application apparatus according to claim 1, further comprising:
a temperature adjusting unit that adjusts a temperature of the substrate before the chemical liquid is applied to the substrate,
wherein the detection unit is provided in the temperature adjusting unit.

4. The chemical liquid application apparatus according to claim 1, wherein
the mark is arranged between shots of the substrate.

5. The chemical liquid application apparatus according to claim 1, wherein
the mark is a scribe line between shots of the substrate.

6. The chemical liquid application apparatus according to claim 1, wherein
the control unit calculates the center position of the shot map from coordinates of the mark in the shot map and a size of each shot in the shot map.

7. The chemical liquid application apparatus according to claim 1, wherein
when an offset value that intentionally shifts the center position of the shot map is set, the control unit calculates the center position of the shot map from the position of the mark and the offset value.

8. The chemical liquid application apparatus according to claim 1, wherein
a removal width of the chemical liquid on the edge of the substrate is large on a side far from the center position of the shot map and is small on a side near the center position of the shot map.

9. The chemical liquid application apparatus according to claim 8, further comprising:
a nozzle that is arranged above the spinner and applies a liquid for removing the chemical liquid applied to the substrate to the edge of the substrate,
wherein the nozzle applies the liquid to the edge of the substrate rotating on the spinner around the center position of the shot map as a rotation axis.

10. The chemical liquid application apparatus according to claim 1, wherein
the chemical liquid includes one of materials of an SOC film, an SOG film, and an adhesive film.

11. A manufacturing method of a semiconductor device performed by a chemical liquid application apparatus that applies a chemical liquid to a substrate and removes the chemical liquid on an edge of the substrate by a predetermined width in a state where the substrate is being rotated by a spinner, the manufacturing method comprising:
detecting a position of a mark on the substrate;
calculating a center position of a shot map from the position of the mark; and
causing the center position of the shot map to coincide with a rotating center of the spinner when transferring the substrate onto the spinner.

12. The manufacturing method of a semiconductor device according to claim 11, further comprising:
detecting the position of the mark on the substrate while transferring the substrate onto the spinner.

13. The manufacturing method of a semiconductor device according to claim 11, further comprising:
detecting the position of the mark on the substrate when adjusting a temperature of the substrate before the chemical liquid is applied to the substrate.

14. The manufacturing method of a semiconductor device according to claim 11, wherein
the mark is arranged between shots of the substrate.

15. The manufacturing method of a semiconductor device according to claim 11, wherein
the mark is a scribe line between shots of the substrate.

16. The manufacturing method of a semiconductor device according to claim 11, further comprising:
calculating the center position of the shot map from coordinates of the mark in the shot map and a size of each shot in the shot map.

17. The manufacturing method of a semiconductor device according to claim 11, wherein
when an offset value that intentionally shifts the center position of the shot map is set, the center position of the shot map is calculated from the position of the mark and the offset value.

18. The manufacturing method of a semiconductor device according to claim 11, wherein
a removal width of the chemical liquid on the edge of the substrate is large on a side far from the center position of the shot map and is small on a side near the center position of the shot map.

19. The manufacturing method of a semiconductor device according to claim 18, further comprising:
applying a liquid for removing the chemical liquid applied to the substrate to the edge of the substrate rotating on the spinner around the center position of the shot map as a rotation axis.

20. The manufacturing method of a semiconductor device according to claim 11, wherein
one of an SOC film, an SOG film, and an adhesive film is formed on the substrate by performing baking processing on the chemical liquid applied to the substrate.
